(19) United States
(12) Patent Application Publication
(10) Pub. No.: US 2026/0371597 A1
(43) Pub. Date: Nov. 19, 2026

(54) MEMORY DEVICE AND METHOD OF MANUFACTURING THE MEMORY DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 19/380,058

(22) Filed: Nov. 5, 2025

(30) Foreign Application Priority Data
May 19, 2025 (KR) 10-2025-0064612

(51) Int. Cl. H10B 43/35; H10B 43/10; H10B 43/27

(52) U.S. Cl. CPC H10B 43/35; H10B 43/10; H10B 43/27

(57) ABSTRACT

A memory device according to an embodiment of the present disclosure includes cell plugs penetrating through a stacked structure, bit lines disposed over the cell plugs, cell contacts disposed between the cell plugs and the bit lines, and air gaps defined between the bit lines. The air gaps extend between the cell contacts.

### CROSS-REFERENCE TO RELATED APPLICATION

The present application claims priority under 35 U.S.C. § 119(a) to Korean patent application number 10-2025-0064612 filed on May 19, 2025, in the Korean Intellectual Property Office, the entire disclosure of which is incorporated herein by reference.

### BACKGROUND

### 1. Technical Field

The present disclosure generally relates to a memory device and a method of manufacturing the memory device, and more particularly, to a memory device including memory blocks having a three-dimensional structure and a method of manufacturing the memory device including the memory blocks having the three-dimensional structure.

### 2. Related Art

A memory device may be a non-volatile memory device which retains stored data even when supplied power is interrupted. A non-volatile memory device may have a two-dimensional structure or a three-dimensional structure according to how memory cells are arranged. Memory cells of a non-volatile memory device having a two-dimensional structure may be arranged in a single layer on a substrate. Memory cells of a non-volatile memory device having a three-dimensional structure may be stacked in a vertical direction on the substrate. Because the integration density of a non-volatile memory device having a three-dimensional structure is higher than that of a non-volatile memory device having a two-dimensional structure, electronic devices are increasingly being manufactured with non-volatile memory devices having a three-dimensional structure.

### SUMMARY

A memory device according to an embodiment of the present disclosure may include cell plugs penetrating through a stacked structure, bit lines disposed over the cell plugs, cell contacts disposed between the cell plugs and the bit lines, and air gaps defined between the bit lines, wherein the air gaps extend between the cell contacts.

A method of manufacturing a memory device according to an embodiment of the present disclosure may include forming a first upper insulating layer on a cell plug, forming a cell contact which penetrates through the first upper insulating layer and is coupled to the cell plug, forming a second upper insulating layer and a third upper insulating layer over the first upper insulating layer, forming an opening which penetrates through the second and third upper insulating layers and exposes the cell contact, forming a bit line contact which fills a part of the opening and exposes a part of a side surface of the second upper insulating layer, forming a bit line which is coupled to the bit line contact, etching a part of the second upper insulating layer and a part of the first upper insulating layer through the side surface of the second upper insulating layer which is exposed, and forming a fourth upper insulating layer which covers the bit line, wherein an air gap defined by the bit line and the fourth upper insulating layer extends between the cell contact and the first upper insulating layer.

### BRIEF DESCRIPTION OF THE DRAWINGS

FIG. 1 is a block diagram illustrating a memory device according to an embodiment of the present disclosure;

FIG. 2 is a diagram illustrating a structure of a memory cell array according to an embodiment of the present disclosure;

FIG. 3 is a plan view illustrating a layout of a memory device according to an embodiment of the present disclosure;

FIGS. 4A-4G are diagrams illustrating a structure of a memory device according to an embodiment of the present disclosure;

FIGS. 5A-5G are diagrams illustrating a manufacturing method of a memory device according to an embodiment of the present disclosure;

FIG. 6 is a diagram illustrating a structure of a memory device including a bonding pad according to an embodiment of the present disclosure;

FIG. 7 is a diagram illustrating a memory card system to which a memory device of the present disclosure is applied; and

FIG. 8 is a block diagram illustrating a Solid-State Drive (SSD) system to which a memory device of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments are described with reference to the accompanying drawings for those skilled in the art to be able to implement the technical spirit of the present disclosure.

Various embodiments of the present disclosure are directed to a technology which may improve the performance of a memory device including a cell plug, a bit line, and contacts coupling the bit line and the cell plug, while simplifying a process of manufacturing the memory device.

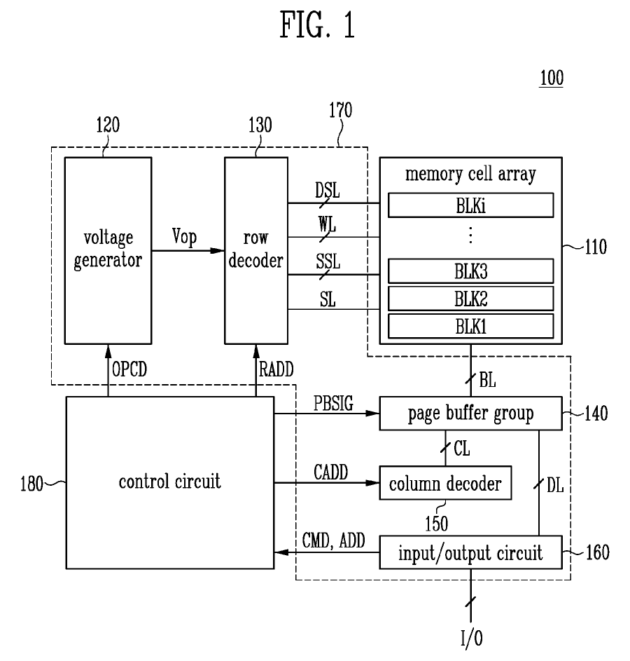

FIG. 1 is a block diagram illustrating a memory device 100 according to an embodiment of the present disclosure.

Referring to FIG. 1, the memory device 100 may include a memory cell array 110, a peripheral circuit 170, and a control circuit 180.

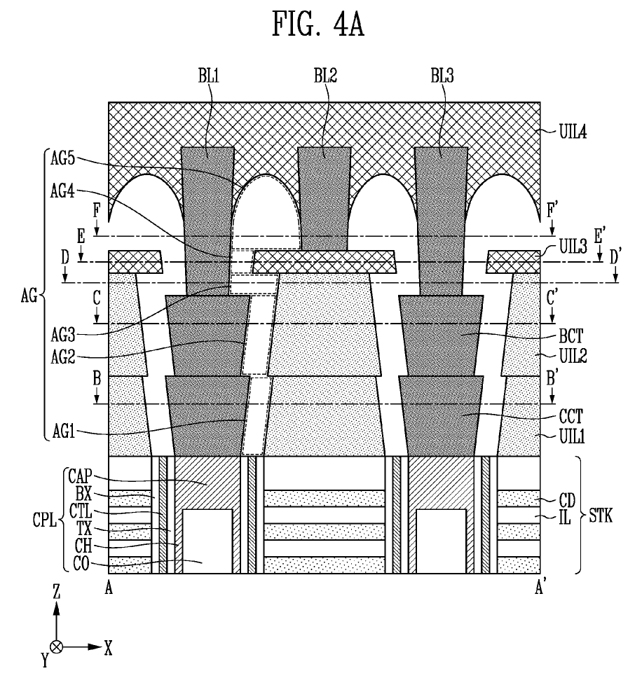

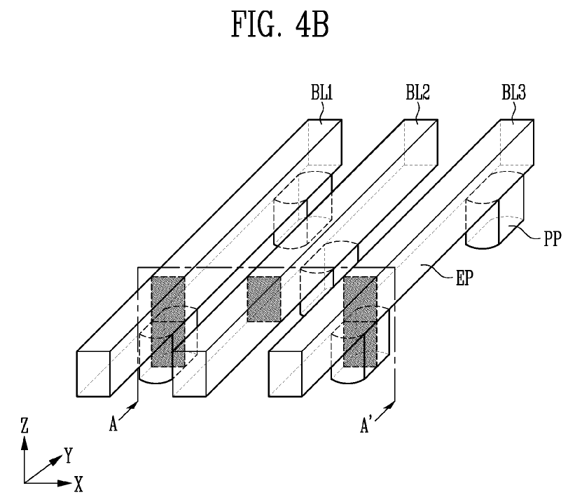

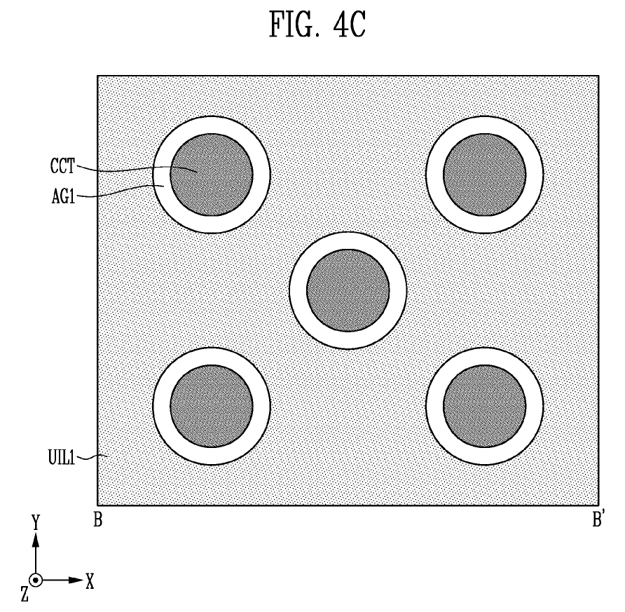

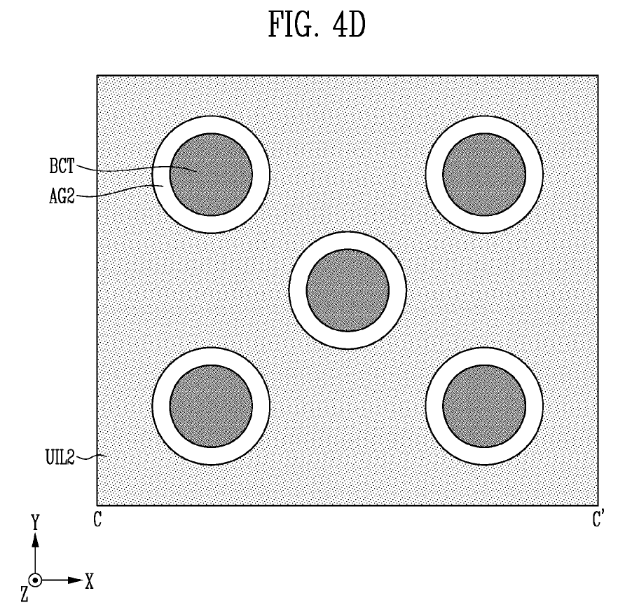

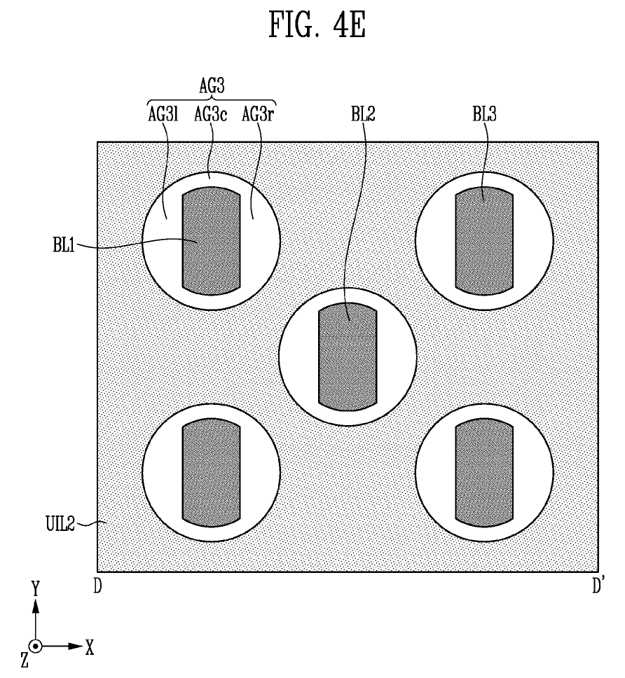

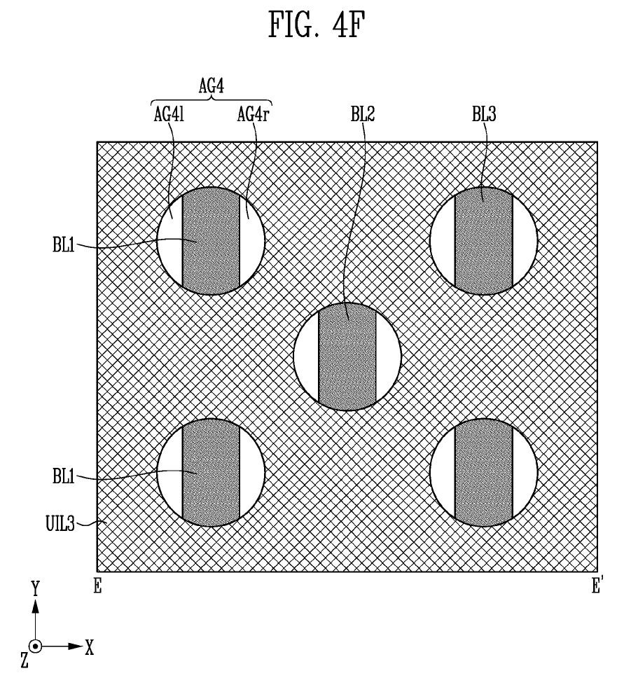

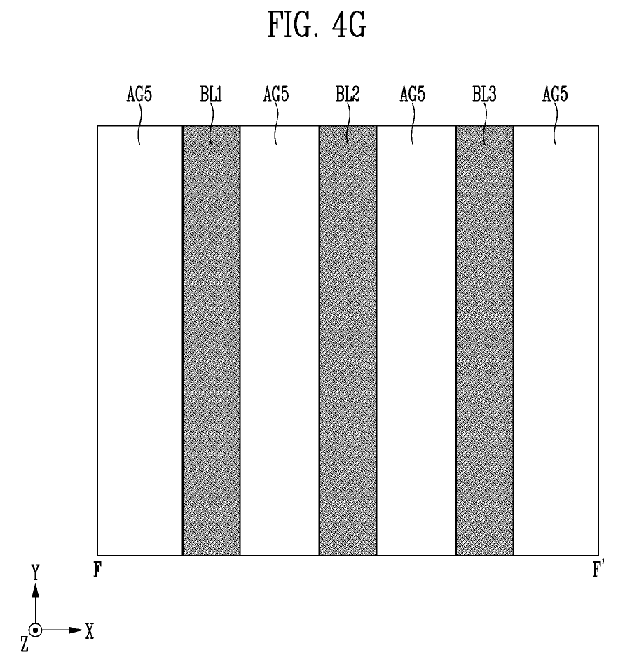

The memory cell array 110 may include first to i-th memory blocks BLK1 to BLKi. Each of the first to i-th memory blocks BLK1 to BLKi may include memory cells capable of storing data. Drain select lines DSL, word lines WL, source select lines SSL, and a source line SL may be coupled to each of the first to i-th memory blocks BLK1 to BLKi. Bit lines BL may be coupled in common to the first to i-th memory blocks BLK1 to BLKi. According to the present disclosure, an air gap may be formed between the bit lines BL, thereby reducing the parasitic capacitance between the bit lines BL compared to a case where no air gap is formed between the bit lines BL. The air gap is described below with reference to FIGS. 4A-4F or the like.

The first to i-th memory blocks BLK1 to BLKi may have a three-dimensional structure. Memory blocks having a three-dimensional structure may include memory cells stacked in a vertical or normal direction on a substrate.

The memory cells may store one, two, or more bits of data according to a program method. For example, a method in which one bit of data is stored in one memory cell is referred to as a single-level cell method, and a method in which two bits of data are stored is referred to as multi-level cell method. A method in which three bits of data are stored in one memory cell is referred to as a triple-level cell method, and a method in which four bits of data are stored is referred to as a quad-level cell method. In addition, five or more bits of data may be stored in one memory cell.

The peripheral circuit 170 may be configured to perform a program operation to store data in the memory cell array 110, a read operation to output data stored in the memory cell array 110, and an erase operation to erase data stored in the memory cell array 110. The peripheral circuit 170 may include a voltage generator 120, a row decoder 130, a page buffer group 140, a column decoder 150, and an input/output circuit 160.

The voltage generator 120 may generate various operating voltages Vop used for the program operation, the read operation, or the erase operation in response to an operation code OPCD. For example, the voltage generator 120 may be configured to generate program voltages, turn-on voltages, turn-off voltages, negative voltages, precharge voltages, verify voltages, read voltages, pass voltages, and/or erase voltages in response to the operation code OPCD. The operating voltages Vop generated at the voltage generator 120 may be applied to the drain select lines DSL, the word lines WL, the source select lines SSL, and the source line SL of a selected memory block via the row decoder 130.

The program voltages may be applied to a selected word line of the word lines WL in a program operation, and may be used to increase a threshold voltage of memory cells coupled to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or the source select transistors. For example, the turn-off voltage may be set to 0 V.

The precharge voltages may be higher than 0 V and may be applied to the bit lines during a read operation. The verify voltages may be used during a verify operation to determine whether a threshold voltage of selected memory cells has risen to a target level. The verify voltages may be set at various levels depending on the target level and may be applied to the selected word line. The read voltages may be applied to the selected word line during a read operation of the selected memory cells. For example, the read voltages may be set to various levels depending on a program method of the selected memory cells. The pass voltages may be applied to unselected word lines of the word lines WL during a program or read operation, which may be used to turn on memory cells coupled to the unselected word lines. The erase voltages may be used during an erase operation to erase memory cells included in the selected memory block and may be applied to the source line SL.

The row decoder 130 may transfer the operating voltages Vop to the drain select lines DSL, the word lines WL, the source select lines SSL, and the source line SL coupled to the selected memory block according to a row address RADD. For example, the row decoder 130 may be coupled to the voltage generator 120 via global lines, and may be coupled to the first to i-th memory blocks BLK1 to BLKi via the drain select lines DSL, the word lines WL, the source select lines SSL, and the source line SL.

The page buffer group 140 may include page buffers (not shown) coupled to the first to i-th memory blocks BLK1 to BLKi, respectively. Each of the page buffers may be coupled to the first to i-th memory blocks BLK1 to BLKi via the bit lines BL. In a read operation, the page buffers may sense, in response to page buffer control signals PBSIG, a current or voltage of bit lines which varies according to the threshold voltage of the selected memory cells, and may store the sensed data.

The column decoder 150 may transfer data between the page buffer group 140 and the input/output circuit 160 in response to a column address CADD. For example, the column decoder 150 may be coupled to the page buffer group 140 via column lines CL and may transfer enable signals via the column lines CL. The page buffers included in the page buffer group 140 may receive or output data via data lines DL in response to the enable signals.

The input/output circuit 160 may receive or output a command CMD, an address ADD, or data via input/output lines I/O. For example, the input/output circuit 160 may transfer the command CMD and the address ADD received from an external controller via the input/output lines I/O to the control circuit 180, and the input/output circuit 160 may transfer the data received from the external controller via the input/output lines I/O to the page buffer group 140. Alternatively, the input/output circuit 160 may output data received from the page buffer group 140 to the external controller via the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 corresponds to a program operation, the control circuit 180 may control the peripheral circuit 170 so that the program operation of the memory block selected by the address ADD is performed. When the command CMD input to the control circuit 180 corresponds to a read operation, the control circuit 180 may control the peripheral circuit 170 to perform the read operation of the memory block selected by the address ADD and output the read data. When the command CMD input to the control circuit 180 corresponds to an erase operation, the control circuit 180 may control the peripheral circuit 170 to perform the erase operation of the selected memory block.

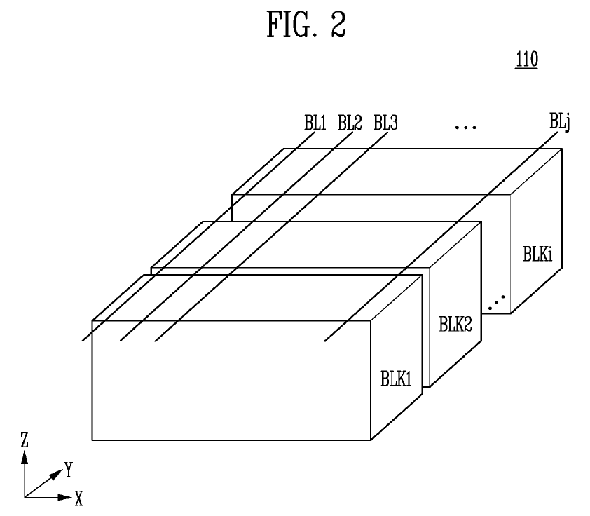

FIG. 2 is a diagram illustrating a structure of the memory cell array 110 according to an embodiment of the present disclosure.

Referring to FIG. 2, the memory cell array 110 may include the first to i-th memory blocks BLK1 to BLKi. The first to i-th memory blocks BLK1 to BLKi may be arranged to be spaced apart from each other in a Y direction. Each of the first to i-th memory blocks BLK1 to BLKi may extend in an X direction.

The first to i-th memory blocks BLK1 to BLKi may be coupled in common to first to j-th bit lines BL1 to BLj. For example, the first to j-th bit lines BL1 to BLj may extend in the Y direction and may be arranged to be spaced apart from each other in the X direction. Each of the first to j-th bit lines BL1 to BLj may be coupled to the first to i-th memory blocks BLK1 to BLKi on the first to i-th memory blocks BLK1 to BLKi.

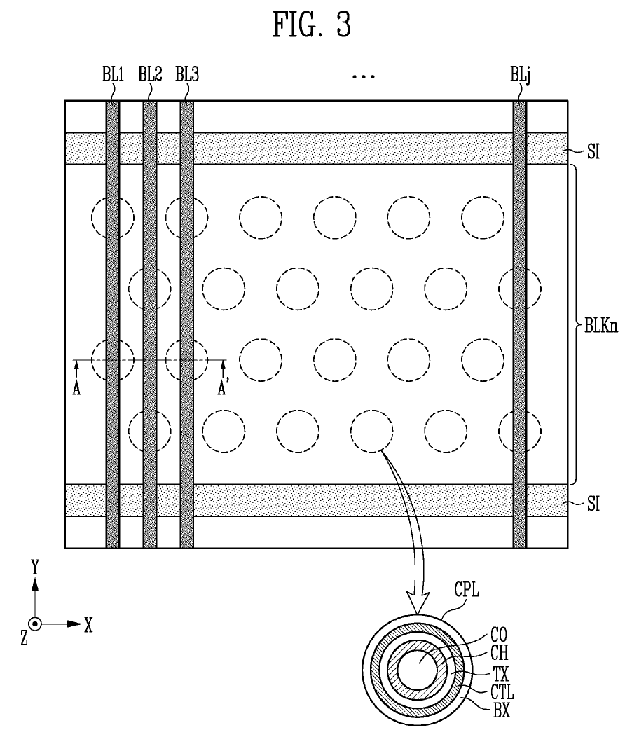

FIG. 3 is a plan view illustrating a layout of a memory device according to an embodiment of the present disclosure.

Referring to FIG. 3, an n-th memory block BLKn, where n is a natural number less than or equal to i, may be separated from adjacent memory blocks by slits SI. For example, the slit SI may be located in the Y direction with respect to the n-th memory block BLKn, and the slit SI may extend in the X direction. The n-th memory block BLKn may be adjacent to another memory block with the slit SI interposed therebetween.

The n-th memory block BLKn may include a plurality of cell plugs CPL. The cell plugs CPL may extend in the vertical direction (e.g., a Z direction) from the substrate. The cell plugs CPL may be arranged in a plurality of rows. Each row may include the cell plugs CPL spaced apart from each other in the X direction. The plurality of rows may be spaced apart from each other in the Y direction. The centers of the cell plugs CPL included in odd-numbered rows may be offset in the X direction from the centers of the cell plugs CPL included in even-numbered rows.

Each of the cell plugs CPL may include a blocking layer BX having a tubular shape, a charge trap layer CTL formed on an inner wall of the blocking layer BX, a tunnel isolation layer TX formed on an inner wall of the charge trap layer CTL, and a channel layer CH formed on an inner wall of the tunnel isolation layer TX, and a core pillar CO formed in a cylindrical shape in a region surrounded by the channel layer CH. The blocking layer BX and the tunnel isolation layer TX may include an oxide layer (e.g., a silicon oxide layer). The charge trap layer CTL may include a nitride layer. The channel layer CH may include a doped silicon layer. The core pillar CO may include an insulating layer or a conductive layer. The blocking layer BX, the charge trap layer CTL, the tunnel isolation layer TX, the channel layer CH, and the core pillar CO included in the cell plug CPL may extend in the vertical direction (i.e., the Z direction).

The first to j-th bit lines BL1 to BLj may be positioned on the n-th memory block BLKn. The first to j-th bit lines BL1 to BLj may be arranged to be spaced apart from each other in the X direction. Each of the first to j-th bit lines BL1 to BLj may extend in the Y direction. The first to j-th bit lines BL1 to BLj may include a conductive material (e.g., copper (Cu) or molybdenum (Mo)).

Each of the first to j-th bit lines BL1 to BLj may be coupled to at least one cell plug CPL. For example, the first bit line BL1 may be coupled to the cell plugs CPL included in the odd-numbered rows. Additionally, the second bit line BL2 may be coupled to the cell plugs CPL included in the even-numbered rows.

Referring to FIG. 3, a distance between the centers of adjacent bit lines BL in the X direction (e.g., the first bit line BL1 and the second bit line BL2) may be shorter than a distance between the centers of adjacent cell plugs CPL in the X direction. The shorter the distance between adjacent bit lines BL in the X direction, the greater the parasitic capacitance occurring between the bit lines BL. In the present disclosure, the parasitic capacitance between the bit lines BL may be reduced through air gaps formed between the bit lines BL. The air gaps are described below with reference to FIGS. 4A to 4G.

FIGS. 4A-4G are diagrams illustrating a structure of a memory device according to an embodiment of the present disclosure. FIG. 4A is a cross-sectional view taken along line A-A’ of FIG. 3. FIG. 4B is a perspective view of a structure of the bit lines BL1 to BL3 of FIG. 4A. FIG. 4C is a plan view corresponding to a cross section taken along line B-B’ in FIG. 4A. FIG. 4D is a plan view corresponding to a cross section taken along line C-C’ in FIG. 4A. FIG. 4E is a plan view corresponding to a cross section taken along line D-D’ in FIG. 4A. FIG. 4F is a plan view corresponding to a cross section taken along line E-E’ in FIG. 4A. FIG. 4G is a plan view corresponding to a cross section taken along line F-F’ in FIG. 4A.

Referring to FIG. 4A, a stacked structure STK may include conductive layers CD and interlayer insulating layers IL. The conductive layers CD and the interlayer insulating layers IL may be alternately stacked in the Z direction. The conductive layers CD may include at least one of tungsten (W), cobalt (Co), nickel (Ni), molybdenum (Mo), silicon (Si), or polysilicon (poly-Si). The conductive layers CD may correspond to gate lines. For example, the conductive layers CD may correspond to the drain select lines DSL, the word lines WL, and the source select lines SSL in FIG. 1. The interlayer insulating layers IL may include an oxide layer. For example, the interlayer insulating layers IL may include a silicon oxide layer.

The cell plugs CPL may penetrate through the stacked structure STK. The cell plugs CPL may extend in the stacked structure STK in the Z direction. The cell plugs CPL may include the blocking layer BX, the charge trap layer CTL, the tunnel isolation layer TX, the channel layer CH, and the core pillar CO. The cell plugs CPL may further include a capping layer CAP coupled to the channel layer CH on the core pillar CO. The capping layer CAP may include a doped silicon layer.

A first upper insulating layer UIL1 may be disposed on the stacked structure STK. The first upper insulating layer UIL1 may cover the stacked structure STK and the cell plugs CPL. The first upper insulating layer UIL1 may be in contact with an upper surface of the stacked structure STK. The first upper insulating layer UIL1 may be spaced apart from the conductive layers CD. The first upper insulating layer UIL1 may be in contact with the uppermost interlayer insulating layer IL among the interlayer insulating layers IL. The thickness of the first upper insulating layer UIL1 may be greater than the thickness of each of the interlayer insulating layers IL. The first upper insulating layer UIL1 may include an insulating material. For example, the first upper insulating layer UIL1 may include an oxide layer.

Cell contacts CCT may be disposed in the first upper insulating layer UIL1. The cell contacts CCT may penetrate through the first upper insulating layer UIL1. The cell contacts CCT may be coupled to the cell plugs CPL. The cell contacts CCT may be in contact with the cell plugs CPL, respectively. The cell contacts CCT may be in contact with the capping layers CAP, respectively. The cell contacts CCT may include a conductive material. For example, the cell contacts CCT may include tungsten (W).

A second upper insulating layer UIL2 may be disposed on the first upper insulating layer UIL1. The second upper insulating layer UIL2 may be in contact with an upper surface of the first upper insulating layer UIL1. In an embodiment, the thickness of the second upper insulating layer UIL2 may be greater than the thickness of the first upper insulating layer UIL1. In another embodiment, the thickness of the second upper insulating layer UIL2 may be less than or equal to the thickness of the first upper insulating layer UIL1. The second upper insulating layer UIL2 may include an insulating material. The second upper insulating layer UIL2 may include the same or a similar material as the first upper insulating layer UIL1. For example, the second upper insulating layer UIL2 may include an oxide layer.

Bit line contacts BCT may be disposed in the second upper insulating layer UIL2. The bit line contacts BCT may partially penetrate the second upper insulating layer UIL2. A level of an upper surface of each of the bit line contacts BCT may be lower than a level of an upper surface of the second upper insulating layer UIL2. A level of a lower surface of each of the bit line contacts BCT may be the same as a level of a lower surface of the second upper insulating layer UIL2. The bit line contacts BCT may be coupled to the cell plugs CPL via the cell contacts CCT. The bit line contacts BCT may be in contact with the cell contacts CCT, respectively. The bit line contacts BCT may include a conductive material. For example, the bit line contacts BCT may include tungsten (W).

A third upper insulating layer UIL3 may be disposed on the second upper insulating layer UIL2. The third upper insulating layer UIL3 may be in contact with the upper surface of the second upper insulating layer UIL2. The third upper insulating layer UIL3 may be spaced apart from the bit line contacts BCT in the Z direction. A level of a lower surface of the third upper insulating layer UIL3 may be higher than the level of the upper surface of each of the bit line contacts BCT. The thickness of the third upper insulating layer UIL3 may be less than the thickness of the first upper insulating layer UIL1 and less than the thickness of the second upper insulating layer UIL2. The third upper insulating layer UIL3 may include an insulating material. The third upper insulating layer UIL3 may include a different material from the first and second upper insulating layers UIL1 and UIL2. The third upper insulating layer UIL3 may include a material having high etch selectivity with respect to the first and second upper insulating layers UIL1 and UIL2. For example, the third upper insulating layer UIL3 may include a nitride layer.

The first to third bit lines BL1 to BL3 may be disposed over the cell plugs CPL. The first to third bit lines BL1 to BL3 may be coupled to the cell plugs CPL via the bit line contacts BCT and the cell contacts CCT. The first to third bit lines BL1 to BL3 may be in contact with the bit line contacts BCT. The first to third bit lines BL1 to BL3 may include a conductive material. For example, the first to third bit lines BL1 to BL3 may include copper (Cu) or molybdenum (Mo).

Referring to FIGS. 4A and 4B, each of the first to third bit lines BL1 to BL3 may include an extension portion EP extending in a horizontal direction and protruding portions PP protruding from the extension portion EP. The extension portions EP may each extend in the Y direction. The protruding portions PP may protrude toward the cell plugs CPL from a lower surface of each of the extension portions EP. The protruding portions PP may overlap with the cell plugs CPL.

The first to third bit lines BL1 to BL3 may be in contact with the third upper insulating layer UIL3. The lower surfaces of the extension portions EP of the first to third bit lines BL1 to BL3 may be in contact with an upper surface of the third upper insulating layer UIL3. The extension portions EP may be disposed on the third upper insulating layer UIL3.

The first to third bit lines BL1 to BL3 may penetrate through the third upper insulating layer UIL3. The first to third bit lines BL1 to BL3 may extend into the second upper insulating layer UIL2. For example, the protruding portions PP of the first to third bit lines BL1 to BL3 may penetrate through the third upper insulating layer UIL3 and extend into the second upper insulating layer UIL2. The protruding portions PP may be in contact with side surfaces of the third upper insulating layer UIL3 exposed through openings formed in the third upper insulating layer UIL3. A part of each of the protruding portions PP may overlap with a part of the second upper insulating layer UIL2 in the horizontal direction. That is, the level of the upper surface of the second upper insulating layer UIL2 may be higher than a level of a lower surface of each of the protruding portions PP. The protruding portions PP may be in contact with the upper surfaces of the bit line contacts BCT.

Referring to FIG. 4B, the width in the X-direction of each of the extension portions EP and the width in the X-direction of each of the protruding portions PP may be substantially the same. Additionally, the extension portion EP and the protruding portions PP included in one bit line (e.g., the third bit line BL3) may be formed integrally. That is, a boundary surface may be lacking between the extension portion EP and the protruding portions PP.

Referring again to FIG. 4A, a fourth upper insulating layer UIL4 may be disposed over the third upper insulating layer UIL3. The fourth upper insulating layer UIL4 may cover the first to third bit lines BL1 to BL3. The fourth upper insulating layer UIL4 may be in contact with the first to third bit lines BL1 to BL3. The fourth upper insulating layer UIL4 may be in contact with a part of a side surface of each of the first to third bit lines BL1 to BL3. The fourth upper insulating layer UIL4 may include an insulating material. For example, the fourth upper insulating layer UIL4 may include the same type of material as the third upper insulating layer UIL3. The fourth upper insulating layer UIL4 may include a nitride layer.

The fourth upper insulating layer UIL4 may include a material with relatively low step coverage. Air gaps AG may be defined between the first to third bit lines BL1 to BL3 by the fourth upper insulating layer UIL4. The air gaps AG may refer to spaces formed between the stacked structure STK and the first to fourth upper insulating layers UIL1 to UIL4. In the present disclosure, the air gaps AG formed between the first to third bit lines BL1 to BL3 may extend between the cell contacts CCT.

The air gaps AG may include first air gaps AG1 positioned between the first upper insulating layer UIL1 and the cell contacts CCT. Referring to FIGS. 4A and 4C, the first air gaps AG1 may surround the cell contacts CCT, respectively. Each of the first air gaps AG1 may have a ring shape surrounding the cell contact CCT. The first upper insulating layer UIL1 and the first air gaps AG1 may be positioned between the adjacent cell contacts CCT.

Referring to FIG. 4A, the first air gaps AG1 may expose upper surfaces of the cell plugs CPL. The first air gaps AG1 may expose upper surfaces of the blocking layer BX, the charge trap layer CTL, and the tunnel isolation layer TX included in each of the cell plugs CPL. In an embodiment, the first air gaps AG1 may expose a part of an upper surface of each of the capping layers CAP. The height of the first air gaps AG1 may be equal to the height of the first upper insulating layer UIL1. Additionally, the height of the first air gaps AG1 may be equal to the height of the cell contacts CCT. The first air gaps AG1 may be defined by the first upper insulating layer UIL1, the cell contacts CCT, and the cell plugs CPL.

The air gaps AG may include second air gaps AG2 positioned between the second upper insulating layer UIL2 and the bit line contacts BCT. Referring to FIGS. 4A and 4D, the second air gaps AG2 may surround the bit line contacts BCT, respectively. Each of the second air gaps AG2 may have a ring shape surrounding the bit line contact BCT. The second upper insulating layer UIL2 and the second air gaps AG2 may be positioned between the adjacent bit line contacts BCT.

Referring to FIG. 4A, the height of the second air gaps AG2 may be equal to the height of the bit line contacts BCT. The second air gaps AG2 may be defined by the second upper insulating layer UIL2 and the bit line contacts BCT.

The air gaps AG may include third air gaps AG3 positioned between the second upper insulating layer UIL2 and the first to third bit lines BL1 to BL3. Referring to FIGS. 4A, 4B, and 4E, the third air gaps AG3 may surround the protruding portions PP of the first to third bit lines BL1 to BL3, respectively. The second upper insulating layer UIL2 and the third air gaps AG3 may be positioned between the adjacent protruding portions PP. Each of the third air gaps AG3 may include a first region AG3l positioned on the left side (e.g., the opposite direction of the X direction) of each of the protruding portions PP of the first to third bit lines BL1 to BL3, a second region AG3r positioned on the right side of each of the protruding portions PP (e.g., the X direction), and third regions AG3c connecting the first region AG3l and the second region AG3r.

Referring to FIG. 4A, the height of the third air gaps AG3 may correspond to the difference between the height of the second upper insulating layer UIL2 and the height of the bit line contacts BCT. The third air gaps AG3 may be defined by the second upper insulating layer UIL2, the first to third bit lines BL1 to BL3, the bit line contacts BCT, and the third upper insulating layer UIL3.

The air gaps AG may include fourth air gaps AG4 positioned between the third upper insulating layer UIL3 and the first to third bit lines BL1 to BL3. Referring to FIGS. 4A, 4B, and 4F, the fourth air gaps AG4 may be positioned between the protruding portions PP of the first to third bit lines BL1 to BL3 and the third upper insulating layer UIL3. The third upper insulating layer UIL3 and the fourth air gaps AG4 may be positioned between the protruding portions PP adjacent in the X direction.

Referring to FIG. 4F, each of the fourth air gaps AG4 may include a first region AG4l positioned on the left side (e.g., the opposite direction of the X direction) of each of the protruding portions PP of the first to third bit lines BL1 to BL3, and a second region AG4r positioned on the right side (e.g., the X direction) of each of the protruding portions PP. The protruding portions PP may be in contact with the side surfaces of the third upper insulating layer UIL3 exposed through the openings formed in the third upper insulating layer UIL3. Therefore, the first region AG4l and the second region AG4r of the fourth air gap AG4 may be separated by the protruding portion PP. The fourth air gap AG4 may correspond to a region of each of the openings in the third upper insulating layer UIL3 in which the protruding portion PP is not formed. The first region AG4l and the second region AG4r of the fourth air gap AG4 may have a symmetrical shape relative to the protruding portion PP.

Referring to FIGS. 4E and 4F, the width in the X-direction of the first region AG4l of the fourth air gap AG4 may be less than the width in the X-direction of the first region AG3l of the third air gap AG3. Referring to FIG. 4A, the distance in the X-direction between the side surface of the third upper insulating layer UIL3 and the protruding portion PP may be shorter than the distance in the X-direction between a side surface of the second upper insulating layer UIL2 and the protruding portion PP.

The height of the fourth air gaps AG4 may correspond to the height of the third upper insulating layer UIL3. The fourth air gaps AG4 may be defined by the third upper insulating layer UIL3 and the first to third bit lines BL1 to BL3.

The air gaps AG may include fifth air gaps AG5 positioned between the first to third bit lines BL1 to BL3. Referring to FIGS. 4A, 4B, and 4G, the fifth air gaps AG5 may be positioned between the extension portions EP of the first to third bit lines BL1 to BL3. The fifth air gaps AG5 may be positioned between the extension portions EP adjacent in the X direction. The fifth air gaps AG5 may extend in the direction in which the first to third bit lines BL1 to BL3 extend (e.g., the Y direction).

Referring to FIG. 4A, the fifth air gaps AG5 may be defined by the fourth upper insulating layer UIL4, the first to third bit lines BL1 to BL3, and the third upper insulating layer UIL3. Because a lower surface of the fourth upper insulating layer UIL4 is a curved surface including concave portions, an upper surface of each of the fifth air gaps AG5 may be convex in the Z direction.

Additionally, a level of the upper surfaces of the fifth air gaps AG5 may be lower than a level of the upper surfaces of the first to third bit lines BL1 to BL3. Upper ends of the first to third bit lines BL1 to BL3 might not overlap with the air gaps AG in the horizontal direction.

The description of the first to fifth air gaps AG1 to AG5 as separate elements with reference to FIGS. 4A to 4G is for convenience of description, and the first to fifth air gaps AG1 to AG5 may extend into and be unified with one another. For example, the first air gaps AG1 and the second air gaps AG2 may extend into one another. Additionally, the second air gaps AG2 may extend into the first region AG3l, the second region AG3r, and the third regions AG3c of the third air gaps AG3. Furthermore, the first region AG3l of the third air gap AG3 may extend into the first region AG4l of the fourth air gaps AG4, and the second region AG3r of the third air gaps AG3 may extend into the second region AG4r of the fourth air gaps AG4. Furthermore, the fourth air gaps AG4 positioned within different openings in the third upper insulating layer UIL3 may extend to each other through the fifth air gaps AG5.

The parasitic capacitance between the first to third bit lines BL1 to BL3 may be reduced by the air gaps AG. Because the air gaps AG include air, which is a low-dielectric material, the air gaps AG may reduce the parasitic capacitance between the first to third bit lines BL1 to BL3. Additionally, according to the present disclosure, the air gaps AG extend between the bit line contacts BCT and between the cell contacts CCT, thereby also being capable of reducing the parasitic capacitance between the bit line contacts BCT and between the cell contacts CCT. Compared to a case where the air gaps AG are formed only between the first to third bit lines BL1 to BL3, when the air gaps AG extend to a level corresponding to the cell contacts CCT, the parasitic capacitance between the first to third bit lines BL1 to BL3 may be further reduced.

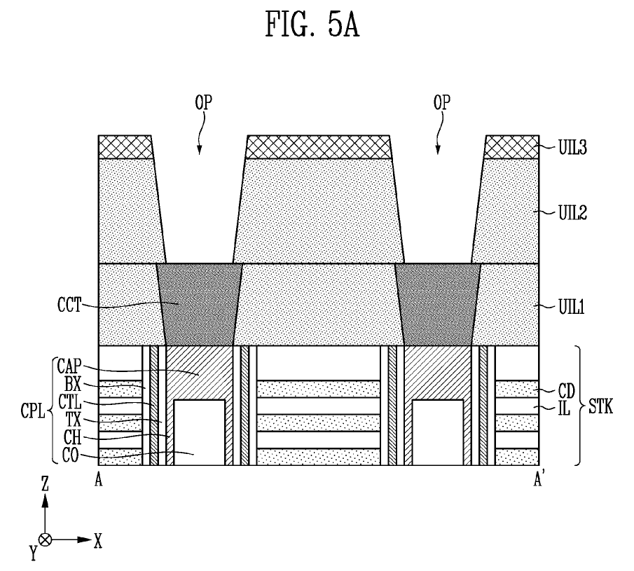

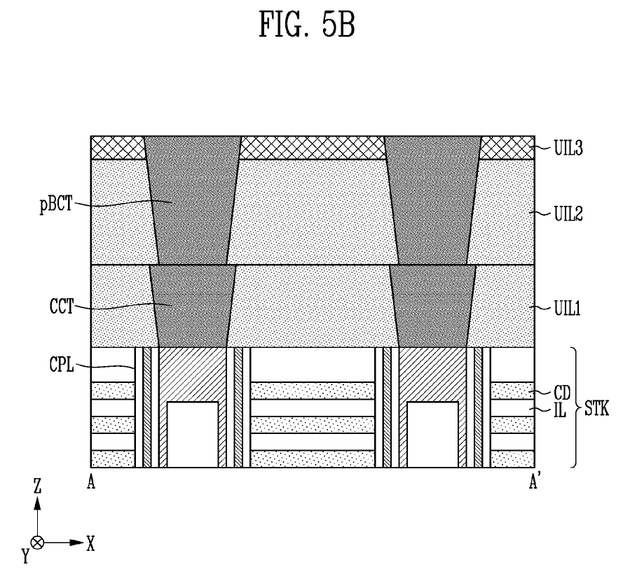

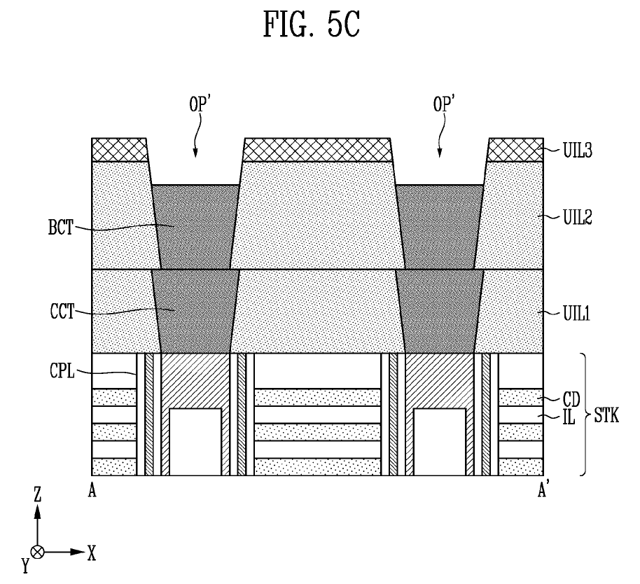

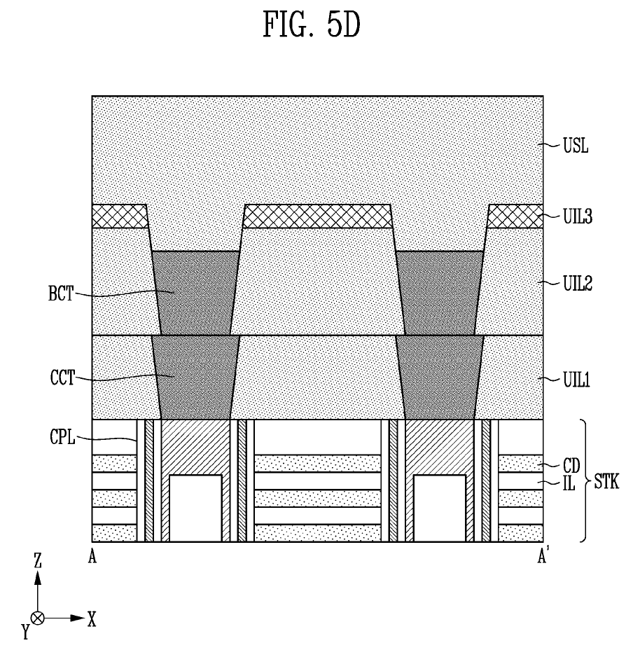

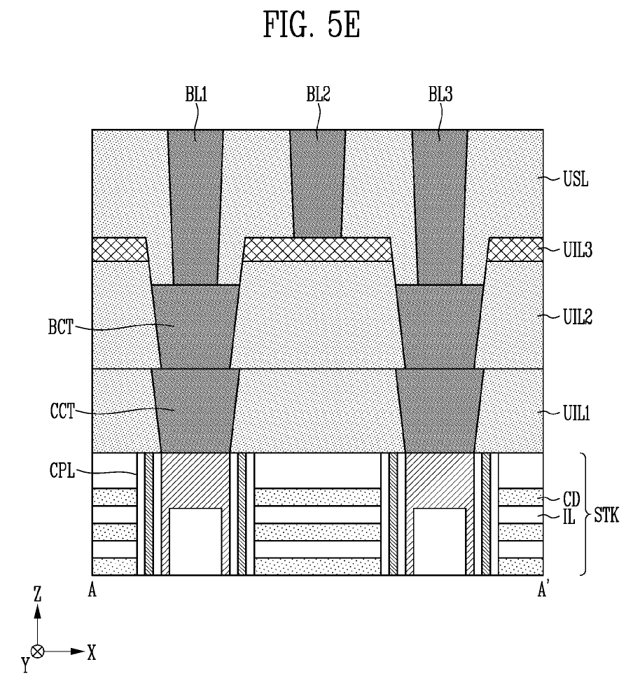

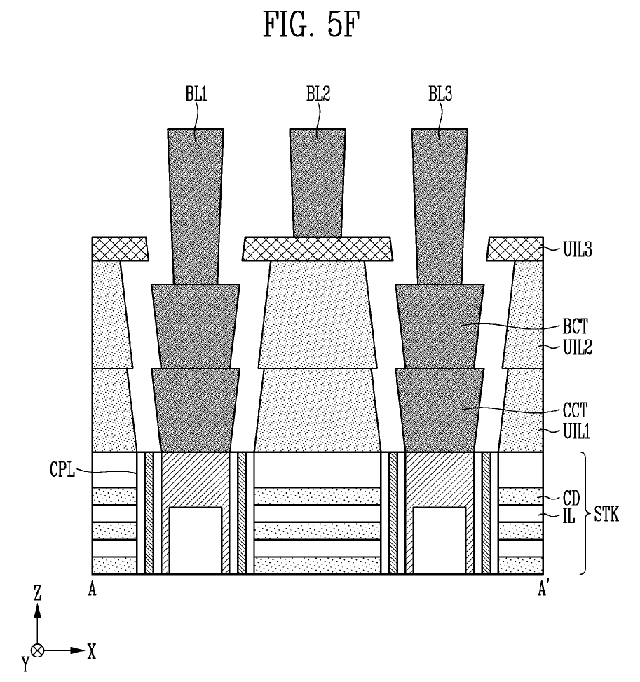

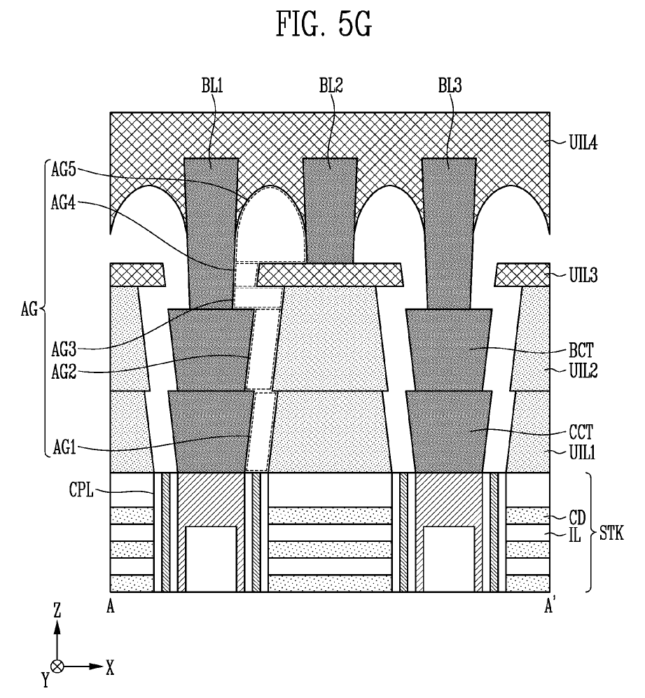

FIGS. 5A-5G are diagrams illustrating a manufacturing method of a memory device according to an embodiment of the present disclosure. FIGS. 5A-5G may correspond to the cross section taken along line A-A’ in FIG. 3.

Referring to FIG. 5A, the stacked structure STK and the cell plugs CPL penetrating through the stacked structure STK may be formed. For example, sacrificial layers and the interlayer insulating layers IL may be alternately stacked in the Z direction. The interlayer insulating layers IL may include an oxide layer. The sacrificial layers may include a material having high etch selectivity with respect to the interlayer insulating layers IL. Subsequently, channel holes penetrating the sacrificial layers and the interlayer insulating layers IL may be formed. Thereafter, the blocking layer BX, the charge trap layer CTL, the tunnel isolation layer TX, the channel layer CH, and the core pillar CO may be sequentially formed in each of the channel holes. Subsequently, the capping layer CAP in contact with the channel layer CH on the core pillar CO may be formed. The blocking layer BX, the charge trap layer CTL, the tunnel isolation layer TX, the channel layer CH, the core pillar CO, and the capping layer CAP may form each of the cell plugs CPL. Subsequently, the sacrificial layers may be replaced with the conductive layers CD.

Subsequently, the first upper insulating layer UIL1 may be formed on the stacked structure STK and the cell plugs CPL. The first upper insulating layer UIL1 may cover the stacked structure STK and the cell plugs CPL.

Subsequently, the cell contacts CCT penetrating through the first upper insulating layer UIL1 and coupled to the cell plugs CPL may be formed. For example, openings penetrating through the first upper insulating layer UIL1 and exposing the cell plugs CPL may be formed by etching a part of the first upper insulating layer UIL1, and a conductive material may be filled into the openings to form the cell contacts CCT.

Subsequently, the second upper insulating layer UIL2 may be formed on the first upper insulating layer UIL1 and the cell contacts CCT. The thickness of the second upper insulating layer UIL2 may be greater than the thickness of the first upper insulating layer UIL1. The second upper insulating layer UIL2 may include the same material or the same type of material as the first upper insulating layer UIL1. For example, the first and second upper insulating layers UIL1 and UIL2 may include oxide layers.

Subsequently, the third upper insulating layer UIL3 may be formed on the second upper insulating layer UIL2. The thickness of the third upper insulating layer UIL3 may be smaller than the thickness of the first upper insulating layer UIL1 and the thickness of the second upper insulating layer UIL2. The third upper insulating layer UIL3 may include a different material from the first and second upper insulating layers UIL1 and UIL2. For example, the third upper insulating layer UIL3 may include a nitride layer.

Subsequently, openings OP penetrating through the second and third upper insulating layers UIL2 and UIL3 may be formed. The openings OP may overlap with the cell plugs CPL and the cell contacts CCT. The openings OP may expose the cell contacts CCT.

Referring to FIG. 5B, preliminary bit line contacts pBC may be formed by filling the openings OP. The preliminary bit line contacts pBC may penetrate through the second and third upper insulating layers UIL2 and UIL3. The preliminary bit line contacts pBC may be coupled to the cell contacts CCT, respectively. The preliminary bit line contacts pBC may be in contact with the cell contacts CCT, respectively.

Referring to FIG. 5C, a part of each of the preliminary bit line contacts pBC may be removed to form the bit line contacts BCT. An upper portion of each of the preliminary bit line contacts pBC may be removed to form the bit line contact BCT. The bit line contacts BCT may partially penetrate the second upper insulating layer UIL2. The level of the upper surface of each of the bit line contacts BCT may be lower than the level of the upper surface of the second upper insulating layer UIL2.

As the part of each of the preliminary bit line contacts pBC is removed, openings OP’ may be formed. Each of the openings OP’ may correspond to a part of each of the openings OP in FIG. 5A. Through the openings OP’, the side surfaces of the third upper insulating layer UIL3 may be exposed. Additionally, the side surfaces of the second upper insulating layer UIL2 may be exposed through the openings OP’. That is, the bit line contacts BCT and the third upper insulating layer UIL3 may be spaced apart from each other in the Z direction, and the side surfaces of the second upper insulating layer UIL2 may be exposed therebetween.

Referring to FIG. 5D, an upper sacrificial layer USL covering the second and third upper insulating layers UIL2 and UIL3 may be formed. The upper sacrificial layer USL may fill the openings OP’ shown in FIG. 5C. The upper sacrificial layer USL may be in contact with the upper surfaces of the bit line contacts BCT, the side surfaces of the second upper insulating layer UIL2, and the side surfaces and the upper surface of the third upper insulating layer UIL3. The upper sacrificial layer USL may include the same material or the same type of material as the first and second upper insulating layers UIL1 and UIL2. For example, the upper sacrificial layer USL may include an oxide layer.

Referring to FIG. 5E, the first to third bit lines BL1 to BL3 penetrating through the upper sacrificial layer USL may be formed. For example, a part of the upper sacrificial layer USL may be etched to form trenches which expose the upper surfaces of the bit line contacts BCT, the upper surface of the third upper insulating layer UIL3, and the side surfaces of the second and third upper insulating layers UIL2 and UIL3. During the formation of the trenches, the third upper insulating layer UIL3 may serve as an etch stop layer. Subsequently, a conductive material is filled into the trenches to form the first to third bit lines BL1 to BL3. The first to third bit lines BL1 to BL3 may penetrate through the third upper insulating layer UIL3 and extend into the second upper insulating layer UIL2.

The first to third bit lines BL1 to BL3 may be coupled to the bit line contacts BCT. The first to third bit lines BL1 to BL3 may be in contact with the upper surfaces of the bit line contacts BCT. For example, protruding portions (e.g., the protruding portions PP in FIG. 4B) of the first to third bit lines BL1 to BL3 may be in contact with the upper surfaces of the bit line contacts BCT.

The first to third bit lines BL1 to BL3 may be in contact with the upper surface and the side surfaces of the third upper insulating layer UIL3. For example, extension portions (e.g., the extension portions EP in FIG. 4B) of the first to third bit lines BL1 to BL3 may be in contact with the upper surface of the third upper insulating layer UIL3. Additionally, the protruding portions (e.g., the protruding portions PP in FIG. 4B) of the first to third bit lines BL1 to BL3 may be in contact with the side surfaces of the third upper insulating layer UIL3.

The first to third bit lines BL1 to BL3 may be in contact with the side surfaces of the second upper insulating layer UIL2. For example, the protruding portions (e.g., the protruding portions PP in FIG. 4B) of the first to third bit lines BL1 to BL3 may be in contact with the side surfaces of the second upper insulating layer UIL2 which are exposed through the openings OP’ in FIG. 5C. Therefore, as shown in FIG. 4B, side surfaces of the protruding portions (e.g., the protruding portions PP in FIG. 4B) of the first to third bit lines BL1 to BL3 may include a curved surface.

Referring to FIG. 5F, the upper sacrificial layer USL may be removed. As the upper sacrificial layer USL is removed, the side surfaces of the first to third bit lines BL1 to BL3 may be exposed. Additionally, as the upper sacrificial layer USL is removed, the side surfaces of the second upper insulating layer UIL2 may be exposed again. For example, among the side surfaces of the second upper insulating layer UIL2 which are exposed through the openings OP’ shown in FIG. 5C, regions which are not in contact with the first to third bit lines BL1 to BL3 may be exposed.

The second upper insulating layer UIL2 and the first upper insulating layer UIL1 may be etched through the exposed side surfaces of the second upper insulating layer UIL2. The second upper insulating layer UIL2 may be etched, thereby exposing side surfaces of the bit line contacts BCT. Additionally, the first upper insulating layer UIL1 may be etched, thereby exposing side surfaces of the cell contacts CCT. The first upper insulating layer UIL1 may be etched until the upper surfaces of the cell plugs CPL or the upper surface of the stacked structure STK are exposed.

Because the upper sacrificial layer USL includes the same material or the same type of material as the first and second upper insulating layers UIL1 and UIL2, a process of removing the upper sacrificial layer USL and a process of etching the part of each of the first and second upper insulating layers UIL1 and UIL2 may be performed simultaneously. That is, when the process of removing the upper sacrificial layer USL is being performed, the second upper insulating layer UIL2 and the first upper insulating layer UIL1 may be etched successively after the upper sacrificial layer USL is removed. For example, when a wet etching process using the same etchant is being performed, the removal of the upper sacrificial layer USL and the etching of the first and second upper insulating layers UIL1 and UIL2 may all be performed.

Because the third upper insulating layer UIL3 includes a different material from the first and second upper insulating layers UIL1 and UIL2, when the first and second upper insulating layers UIL1 and UIL2 are etched, the third upper insulating layer UIL3 might not be etched. Therefore, the third upper insulating layer UIL3 may physically support the first to third bit lines BL1 to BL3 during the wet etching process.

Referring to FIG. 5G, the fourth upper insulating layer UIL4 covering the first to third bit lines BL1 to BL3 may be formed. As the fourth upper insulating layer UIL4 is formed, the air gaps AG including the first to fifth air gaps AG1 to AG5 may be defined. The air gaps AG may extend from between the first to third bit lines BL1 to BL3 to between the cell contacts CCT.

For example, the air gaps AG may include the first air gaps AG1 corresponding to the region from which the first upper insulating layer UIL1 is etched in FIG. 5F. Additionally, the air gaps AG may include the second air gaps AG2 corresponding to a part of the region from which the second upper insulating layer UIL2 is etched in FIG. 5F. Furthermore, the air gaps AG may include the third air gaps AG3 corresponding to a part of the region from which the upper sacrificial layer USL is removed and another part of the region from which the second upper insulating layer UIL2 is removed in FIG. 5F. Furthermore, the air gaps AG may include the fourth air gaps AG4 corresponding to regions of the openings OP’ in FIG. 5C which are located at the same level as the third upper insulating layer UIL3. Furthermore, the air gaps AG may include the fifth air gaps AG5 surrounded by the first to third bit lines BL1 to BL3 and the third and fourth upper insulating layers UIL3 and UIL4.

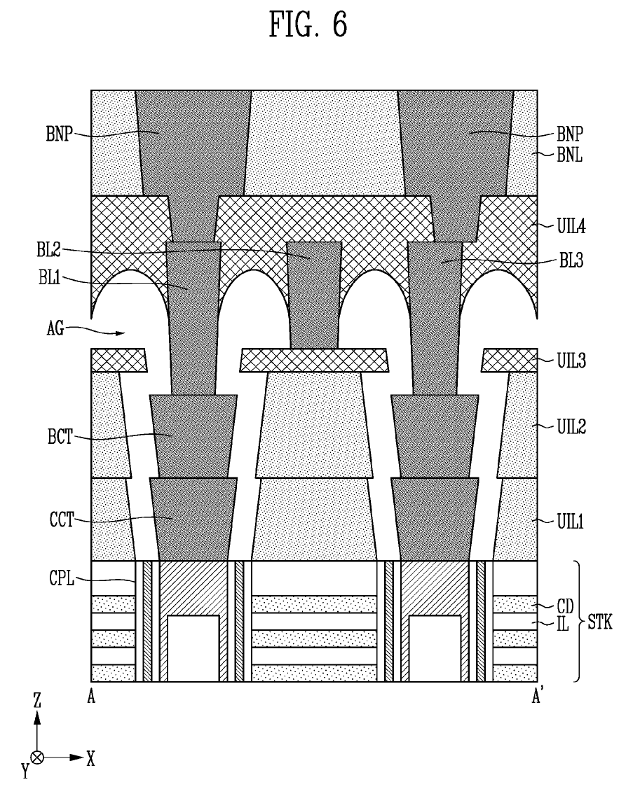

A level of the upper surface of the air gaps AG may be lower than the level of the upper surfaces of the first to third bit lines BL1 to BL3, which is described below with reference to FIG. 6.

FIG. 6 is a diagram illustrating a structure of a memory device including a bonding pad according to an embodiment of the present disclosure.

Referring to FIG. 6, a bonding layer BNL may be formed on the fourth upper insulating layer UIL4. Additionally, bonding pads BNP penetrating through the bonding layer BNL and coupled to the first to third bit lines BL1 to BL3 may be formed. The bonding pads BNP may be electrically coupled to at least one or more of the first to third bit lines BL1 to BL3. The bonding pads BNP may be in contact with at least one or more of the first to third bit lines BL1 to BL3. The bonding pads BNP may include a conductive material (e.g., copper (Cu)).

A level of lower surfaces of the bonding pads BNP may be higher than the level of the upper surfaces of the air gaps AG. That is, the bonding pads BNP may be formed to be spaced apart from the air gaps AG in the Z direction. When the fourth upper insulating layer UIL4 is formed, because the level of the upper surface of the air gaps AG is lower than the level of the upper surfaces of the first to third bit lines BL1 to BL3, the bonding pads BNP may be spaced apart from the air gaps AG.

Therefore, according to the present disclosure, not only when the bonding pads BNP are aligned with a bit line (e.g., the first bit line BL1), but also when the bonding pads BNP are misaligned with a bit line (e.g., the third bit line BL3), the bonding pads BNP might not be coupled to the air gap AG.

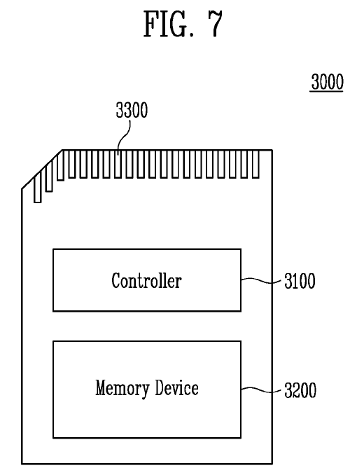

FIG. 7 is a diagram illustrating a memory card system 3000 to which a memory device 3200 of the present disclosure is applied.

Referring to FIG. 7, the memory card system 3000 includes a controller 3100, the memory device 3200, and a connector 3300.

The controller 3100 may be coupled to the memory device 3200. The controller 3100 may be configured to access the memory device 3200. For example, the controller 3100 may be configured to control a program operation, a read operation, or an erase operation of the memory device 3200, or to control a background operation. The controller 3100 may be configured to provide an interface between the memory device 3200 and a host. The controller 3100 may be configured to run firmware to control the memory device 3200. For example, the controller 3100 may include components, such as Random-Access Memory (RAM), a processing unit, a host interface, a memory interface, and an error correction portion.

The controller 3100 may communicate with an external device through the connector 3300. The controller 3100 may communicate with the external device (e.g., a host) based on a particular communication protocol. For example, the controller 3100 is configured to communicate with the external device via at least one of various communication protocols, such as a Universal Serial Bus (USB), a multimedia card (MMC), an embedded MMC (eMMC), Peripheral Component Interconnect (PCI), PCI-express (PCI-E), Advanced Technology Attachment (ATA), Serial-ATA, Parallel-ATA, a Small Computer System Interface (SCSI), an Enhanced Small Disk Interface (ESDI), Integrated Drive Electronics (IDE), Firewire, Universal Flash Storage (UFS), Wi-Fi, Bluetooth, or Non-Volatile Memory express (NVMe). For example, the connector 3300 may be defined by at least one of the various communication protocols described above.

The memory device 3200 may include a plurality of memory cells and may be configured in the same manner as the memory device 100 illustrated in FIG. 1.

The controller 3100 and the memory device 3200 may be integrated into one semiconductor device to form a memory card. For example, the controller 3100 and the memory device 3200 may be integrated into one semiconductor device to constitute a memory card such as a Personal Computer Memory Card International Association (PCMCIA), a Compact Flash (CF) card, a smart media card (SM, SMC), a memory stick, a multimedia card (MMC, RS-MMC, MMCmicro, eMMC), an SD card (SD, miniSD, microSD, SDHC), or Universal Flash Storage (UFS).

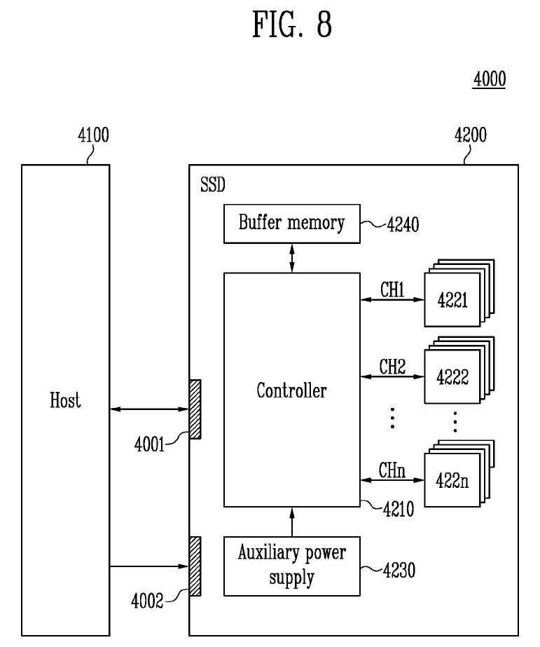

FIG. 8 is a block diagram illustrating a Solid-State Drive (SSD) 4000 system to which a memory device of the present disclosure is applied.

Referring to FIG. 8, the SSD system 4000 may include a host 4100 and an SSD 4200. The SSD 4200 may exchange signals with the host 4100 through a signal connector 4001, and the SSD 4200 may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. For example, the signals may be based on an interface of the host 4100 and the SSD 4200. For example, the signals may be defined by at least one of interfaces such as a Universal Serial Bus (USB), a multimedia card (MMC), an embedded MMC (eMMC), Peripheral Component Interconnect (PCI), PCI-express (PCI-E), Advanced Technology Attachment (ATA), Serial-ATA, Parallel-ATA, a Small Computer System Interface (SCSI), an Enhanced Small Disk Interface (ESDI), Integrated Drive Electronics (IDE), Firewire, Universal Flash Storage (UFS), Wi-Fi, Bluetooth, or Non-Volatile Memory express (NVMe).

The plurality of memory devices 4221 to 422n may include a plurality of memory cells configured to store data. Each of the plurality of memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may receive a power voltage from the host 4100 and may be charged. The auxiliary power supply 4230 may provide the power voltage of the SSD 4200 when the power supply from the host 4100 is not smooth. For example, the auxiliary power supply 4230 may be located in the SSD 4200 or may be located outside the SSD 4200. For example, the auxiliary power supply 4230 may be located on a main board and may provide auxiliary power to the SSD 4200.

The buffer memory 4240 may operate as buffer memory of the SSD 4200. For example, the buffer memory 4240 may store data received from the host 4100 or data received from the plurality of memory devices 4221 to 422n, or the buffer memory 4240 may store metadata (e.g., a mapping table) of the memory devices 4221 and 422n. The buffer memory 4240 may include volatile memory, such as DRAM, SDRAM, DDR SDRAM, or LPDDR SDRAM, or non-volatile memory, such as FRAM, ReRAM, STT-MRAM, or PRAM.

According to embodiments of the present disclosure, the parasitic capacitance between bit lines and the parasitic capacitance between contacts may be reduced, and a process of manufacturing a memory device may be simplified.

What is claimed is:

1. A memory device comprising:
cell plugs penetrating through a stacked structure;
bit lines disposed over the cell plugs;
cell contacts disposed between the cell plugs and the bit lines; and
air gaps defined between the bit lines,
wherein the air gaps extend between the cell contacts.

2. The memory device of claim 1, wherein the cell contacts are in contact with the cell plugs, respectively.

3. The memory device of claim 1, further comprising a first upper insulating layer covering the stacked structure,
wherein the cell contacts penetrate through the first upper insulating layer, and
wherein the air gaps include a first air gap positioned between the first upper insulating layer and at least one of the cell contacts.

4. The memory device of claim 3, wherein at least a part of an upper surface of each of the cell plugs is exposed to the first air gap.

5. The memory device of claim 3, further comprising:
a second upper insulating layer on the first upper insulating layer; and
bit line contacts disposed in the second upper insulating layer and coupling the cell contacts to the bit lines,
wherein the air gaps include a second air gap positioned between the second upper insulating layer and at least one of the bit line contacts.

6. The memory device of claim 5, wherein the bit line contacts are in contact with upper surfaces of the cell contacts and in contact with lower surfaces of the bit lines.

7. The memory device of claim 5, wherein the first air gap has a ring shape surrounding the at least one of the cell contacts, and
wherein the second air gap has a ring shape surrounding the at least one of the bit line contacts.

8. The memory device of claim 5, wherein the bit lines extend into the second upper insulating layer.

9. The memory device of claim 5, wherein a level of an upper surface of each of the bit line contacts is lower than a level of an upper surface of the second upper insulating layer.

10. The memory device of claim 5, wherein the air gaps include a third air gap positioned between the second upper insulating layer and at least one of the bit lines.

11. The memory device of claim 5, further comprising a third upper insulating layer on the second upper insulating layer,
wherein the bit lines penetrate through the third upper insulating layer, and
wherein the air gaps include a fourth air gap positioned between the third upper insulating layer and at least one of the bit lines.

12. The memory device of claim 11, wherein the third upper insulating layer includes a different material from the first and second upper insulating layers.

13. The memory device of claim 11, wherein a distance between a side surface of the third upper insulating layer and a side surface of a first bit line among the bit lines is shorter than a distance between a side surface of the second upper insulating layer and the side surface of the first bit line.

14. The memory device of claim 11, wherein the third upper insulating layer includes openings overlapping with the cell contacts, and
wherein the bit lines are in contact with an upper surface of the third upper insulating layer and side surfaces of the third upper insulating layer which are exposed through the openings included in the third upper insulating layer.

15. The memory device of claim 14, wherein the fourth air gap includes the openings included in the third upper insulating layer and excludes the bit lines extending through the openings included in the third upper insulating layer.

16. The memory device of claim 11, wherein the bit line contacts are spaced apart from the third upper insulating layer in a vertical direction.

17. The memory device of claim 11, further comprising a fourth upper insulating layer disposed over the third upper insulating layer and covering the bit lines,
wherein the air gaps include a fifth air gap defined by the fourth upper insulating layer and the bit lines.

18. The memory device of claim 17, wherein the third upper insulating layer and the fourth upper insulating layer include a nitride material.

19. The memory device of claim 17, wherein the fifth air gap extends in a direction in which the bit lines extend.

20. The memory device of claim 1, further comprising bonding pads electrically coupled to one or more of the bit lines,
wherein a level of a lower surface of each of the bonding pads is higher than a level of an upper surface of each of the air gaps.
